(19) United States
(12) Patent Application Publication
(10) Pub. No.: US 2006/0211196 A1
(43) Pub. Date: Sep. 21, 2006

(54) Semiconductor memory device and manufacturing method thereof

(75) Inventors: Toshiharu Tanaka, Yokohama-shi (JP); Masaru Kito, Yokohama-shi (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(73) Assignee: Kabushiki Kaisha Toshiba, Minato-ku (JP)

(21) Appl. No.: 11/375,018

(22) Filed: Mar. 15, 2006

(30) Foreign Application Priority Data
Mar. 15, 2005 (JP) 2005-072800

(51) Int. Cl. H01L 21/8242

(52) U.S. Cl. 438/243; 438/239

(57) ABSTRACT

A semiconductor memory device includes: a semiconductor substrate; a plurality of trench capacitors each including a capacitor dielectric film formed on a sidewall of a first trench to be formed in the semiconductor substrate, a storage node formed so as to bury the first trench via the capacitor dielectric film, and a buried plate formed in the semiconductor substrate so as to surround the first trench; a device isolation trench formed in the semiconductor substrate so as to define a device formation area across neighboring two trench capacitors; a first insulating film for device isolation formed of a first insulating material to surround the device isolation trench; a plurality of transistors formed on the device forming area respectively including a gate electrode formed on the semiconductor substrate via a gate insulating film so as to be a word line continuing in one direction and source/drain diffusion layers formed on the surface layer of the semiconductor substrate sandwiching the gate electrode such that one of them is shared and the other corresponds to the storage node; a second insulating film formed on the upper side of the first trench so as to contact the top surface of the storage node and face the other source/drain diffusion layer spaced apart by a contact hole for a Surface Strap, the second insulating film being formed of a second insulating material different from the first material; a buried contact layer formed so as to be self-aligned to the gate electrodes to bury the contact hole to connect the storage node and the other source/drain diffusion layer; and a bit line to be connected to the one of the source/drain diffusion layers.

### CROSS REFERENCE TO RELATED APPLICATIONS

This application claims benefit of priority under 35USC §119 to Japanese Patent Application No. 2005-72800, filed on Mar. 15, 2005, the contents of which are incorporated by reference herein.

### BACKGROUND OF THE INVENTION

1. Field of the Invention

The present invention relates to a semiconductor memory device and a manufacturing method thereof.

2. Related Background Art

A semiconductor memory device comprising an array of DRAM cells with a trench capacitor, may have a Surface Strap (hereinafter, simply refers to as “SS”) structure in which a transistor and a capacitor are connected by a buried contact layer provided so as to extend across the surfaces of the storage node (hereinafter, simply refers to as “SN”) of the trench capacitor and the diffusion layer of the transistor corresponding to the storage node.

Conventionally, in a trench DRAM having such an SS structure, both a Trench Top Oxide to be buried on the top portion of the trench capacitor (hereinafter, simply refers to as “TTO”) and a device isolation insulating film have been formed of same insulating material, for example, silicon oxide (SiO₂) film. Therefore, in order to expose the SN of the trench capacitor, when the TTO is etched back to provide a hole for a buried contact layer, the device isolation insulating film contacting the sidewall of an Active Area (hereinafter, simply refers to as “AA”) is also etched back and removed at the same time, thereby exposing the sidewall of the AA. Since poly-silicon doped with an impurity is deposited to form the buried contact layer under this condition, the poly-silicon also contacts the sidewall of the AA, the impurity in the poly-silicon diffuses into the AA side, resulting in the change of the profile of the impurity concentration of the source/drain diffusion layer, which may adversely affect the operation of an array device.

Referring to FIG. 1 to FIG. 8, the above-mentioned problem on a conventional manufacturing method of the DRAM 1 with an SS structure 1 is hereinafter described in more detail.

First, as shown in FIG. 1, by using a known technology, a trench capacitor C, collar oxide 22, and silicon oxide (SiO₂) film 110 that becomes a device isolation insulating film to define the AA are formed in a silicon substrate S. The top portion of the silicon oxide (SiO₂) film 110, which locates in the upper region of the trench, is a TTO.

Then, as shown in FIG. 2, after a gate pattern (44, 46) is formed and source/drain diffusion layers 52, 54 of the AA are formed using a known technology, a barrier silicon nitride (SiN) film 61 is deposited. Further, after a gate interlayer film (not shown) is deposited, it is planarized. FIG. 3 shows a layout chart of the conventional device at the step of manufacture. In addition, FIGS. 1 and 2 are sectional views of the conventional device corresponding to that along the line A-A of FIG. 3, respectively.

Next, a mask (not shown) with a shape corresponding to the arrangement of the SN in the trench capacitor C is provided onto the TTO and the TTO is etched back. Thereby the top portion of the TTO locating above the SN is selectively removed to expose the surface of the SN, providing a hole for a buried contact layer.

However, during the process, a thin portion of the device isolation insulating film 110 running along the sidewall of the AA (shaded portion G) is simultaneously removed by the etching back as shown in FIG. 4 due to low accuracy in alignment of the mask and/or variation in processes. FIG. 5 is a sectional view of FIG. 4 along the line A-A and FIG. 6 is a sectional view of FIG. 4 along the line B-B. As shown in FIG. 6, the portion G of the device isolation insulating film 110 on the sidewall of the AA is removed, thereby a gap is formed resulting in exposure of the sidewall of the AA. Since poly-silicon 37 doped with an impurity (for example; phosphorus (hereinafter, simply refers to as “P”)) is deposited as shown in FIGS. 7 and 8 to form the buried contact layer under this condition, so as to be deposited also onto the exposed surface of the SN. As a result, the poly-silicon also contacts the sidewall of the AA, the impurity in the poly-silicon 37 diffuses also into the AA side as is designated by arrows in FIGS. 7 and 8. In consequence, the impurity concentration profile of the source/drain diffusion layer is changed, which may arise the problem of causing negative effect on the operation of an array device.

### SUMMARY OF THE INVENTION

According to a first aspect of the present invention, there is provided a semiconductor memory device comprising:

a semiconductor substrate;

a plurality of trench capacitors each including a capacitor dielectric film formed on a sidewall of a first trench to be formed in the semiconductor substrate, a storage node formed so as to bury the first trench via the capacitor dielectric film, and a buried plate formed in the semiconductor substrate so as to surround the first trench;

a device isolation trench formed in the semiconductor substrate so as to define a device formation area across neighboring two trench capacitors;

a first insulating film for device isolation formed of a first insulating material to surround the device isolation trench;

a plurality of transistors formed on the device forming area respectively including a gate electrode formed on the semiconductor substrate via a gate insulating film so as to be a word line continuing in one direction and source/drain diffusion layers formed on the surface layer of the semiconductor substrate sandwiching the gate electrode such that one of them is shared and the other corresponds to the storage node;

a second insulating film formed on the upper side of the first trench so as to contact the top surface of the storage node and face the other source/drain diffusion layer spaced apart by a contact hole for a Surface Strap, the second insulating film being formed of a second insulating material different from the first material;

a buried contact layer formed so as to be self-aligned to the gate electrodes to bury the contact hole to connect the storage node and the other source/drain diffusion layer; and

a bit line to be connected to the one of the source/drain diffusion layers.

According to a second aspect of the present invention, there is provided a manufacturing method of a semiconductor memory device comprises:

forming a plurality of trench capacitors by forming a plurality of first trenches on a semiconductor substrate, forming capacitor dielectric films on the sidewalls of the first trenches, forming storage nodes via the capacitor dielectric films so as to bury the first trenches, and forming buried plates in the areas of the semiconductor substrate that surrounds the first trenches;

forming a device isolation trench in the semiconductor substrate so as to define a device forming area extending across neighboring two trench capacitors;

forming a first insulating film for isolating a device by burying the device isolation trench;

forming a first hole from which the storage node is exposed by selectively removing a portion of the device isolation insulation film in the upper area of the first trench;

forming a second insulating film by filling the first hole with insulating material different from that of the first insulating film;

forming a plurality of transistors in the device forming area such that each gate electrode becomes a word line continuing to one direction, one of source/drain diffusion layers is shared by each transistor and the other source/drain diffusion layer corresponds to the storage node;

forming a barrier insulating film on the whole surface of the semiconductor substrate using an insulating material that may have etching selective ratios to the semiconductor substrate and the insulating material of the first insulating film:

forming a contact hole for a Surface Strap by selectively removing the second insulating film using the barrier insulating film as a mask until the top surface of the storage node and the other source/drain diffusion layer are exposed;

forming a buried contact layer so as to be self-aligned to the gate electrode to bury the contact hole; and

forming a bit line to be connected to the other source/drain diffusion layer.

### BRIEF DESCRIPTION OF THE DRAWINGS

In the appended drawings,

FIGS. 1 and 2 are sectional views schematically illustrating a conventional manufacturing method of a trench DRAM with an SS structure;

FIG. 3 is a layout chart of a DRAM after process shown in FIG. 2;

FIG. 4 is a layout chart illustrating a problem on a conventional manufacturing method;

FIG. 5 is a sectional view of FIG. 4 along the line A-A;

FIG. 6 is a sectional view of FIG. 4 along the line B-B;

FIGS. 7 and 8 are sectional views schematically illustrating diffusion of impurity into AA from the polysilicon to form buried contact layers;

FIG. 9 is a top view schematically illustrating a first embodiment of the semiconductor memory device according to the present invention;

FIG. 10 is a sectional view of FIG. 9 along the line A-A;

FIG. 11 is a sectional view of FIG. 9 along the line B-B;

FIGS. 12-18 are sectional views illustrating a manufacturing method of the semiconductor memory device shown in FIG. 9;

FIG. 19 is a sectional view schematically illustrating a second embodiment of the semiconductor memory device according to the present invention; and

FIGS. 20-26 are sectional views illustrating a manufacturing method of the semiconductor memory device shown in FIG. 19.

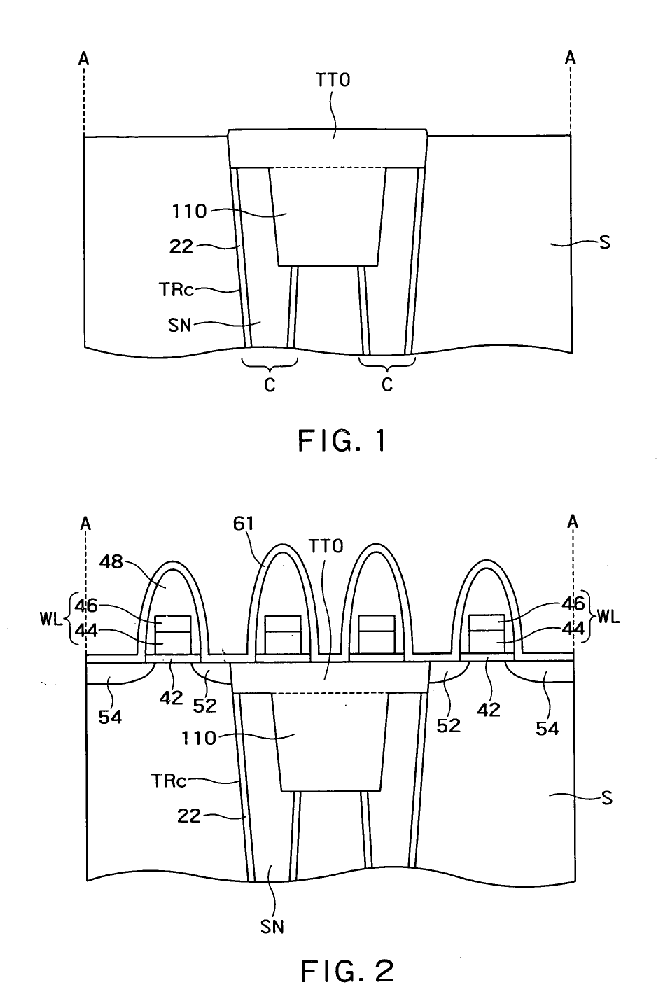

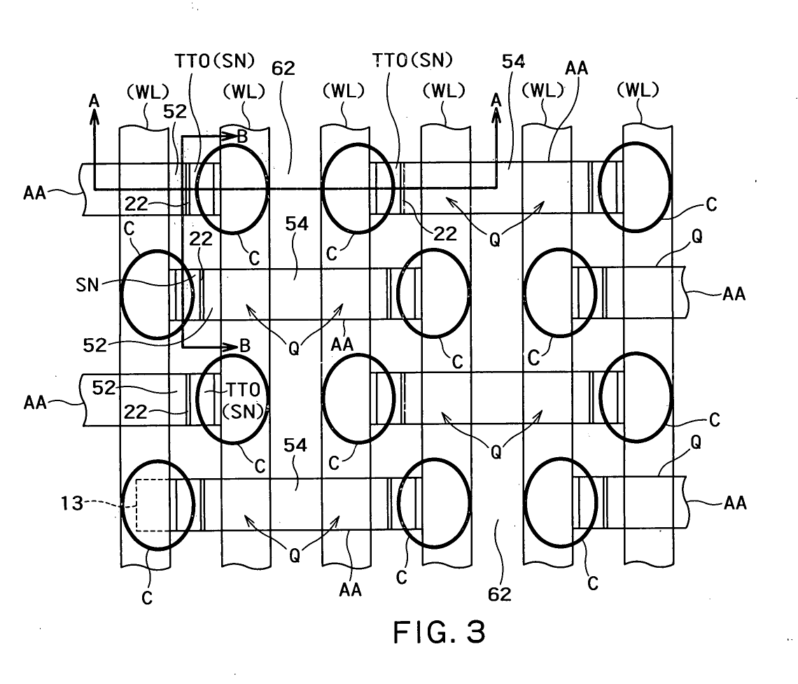

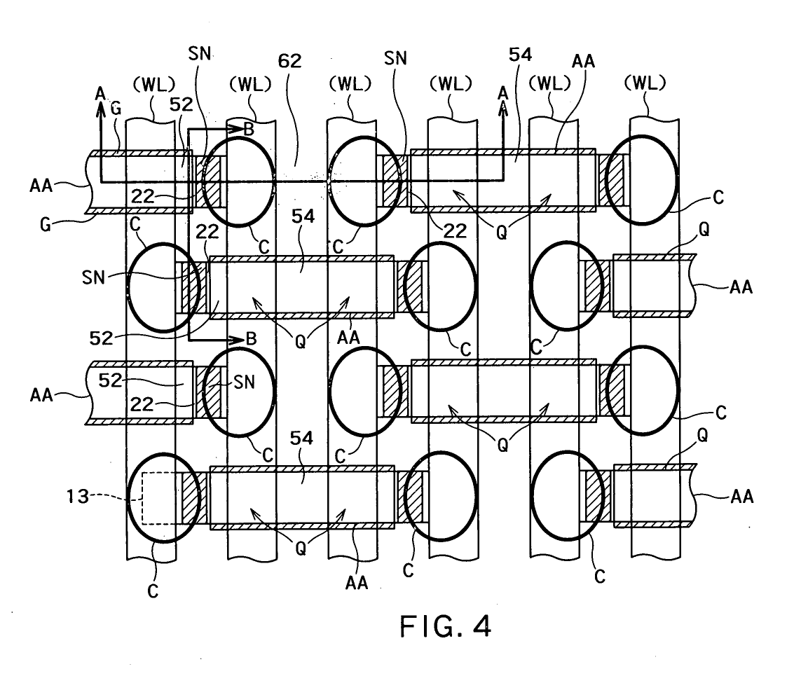

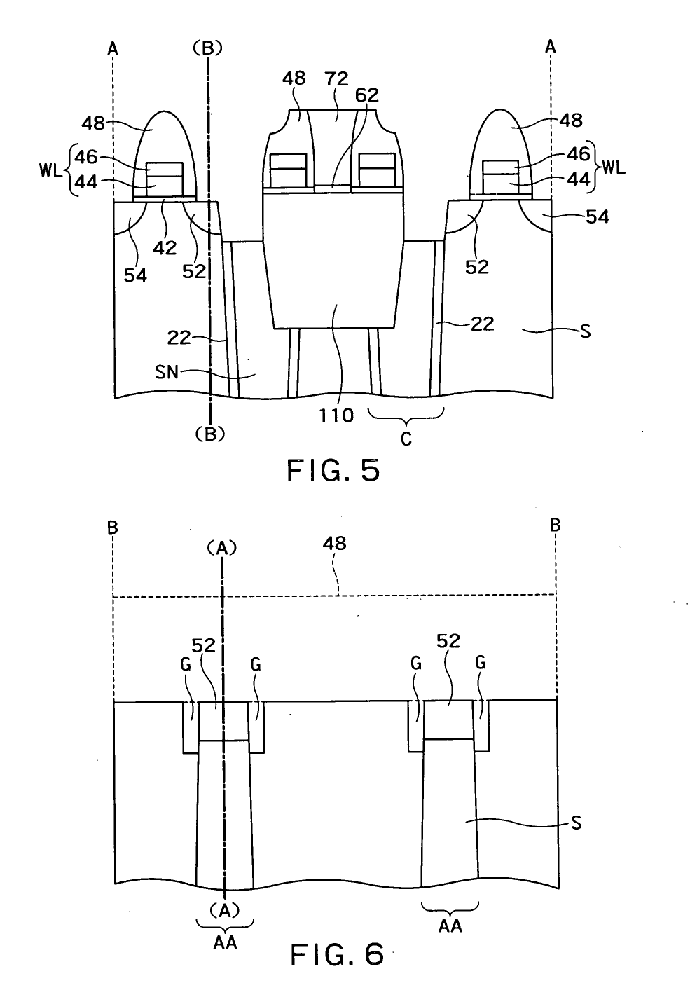

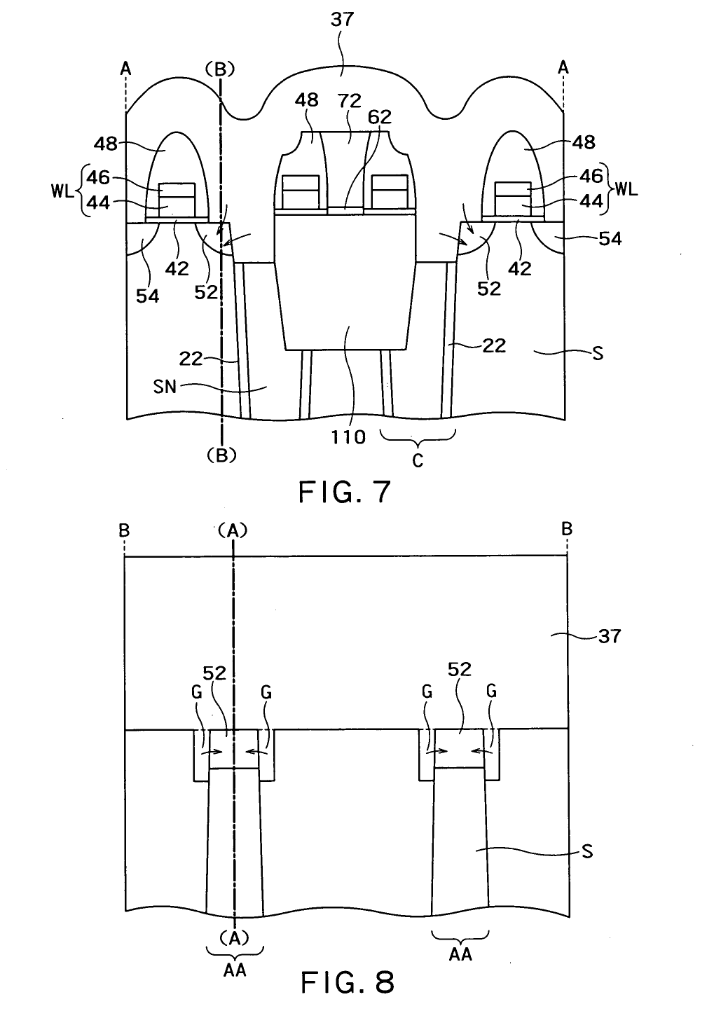

### DETAILED DESCRIPTION OF THE INVENTION

Now, referring to drawings, embodiments according to the present invention will be described below.

### (1) First Embodiment

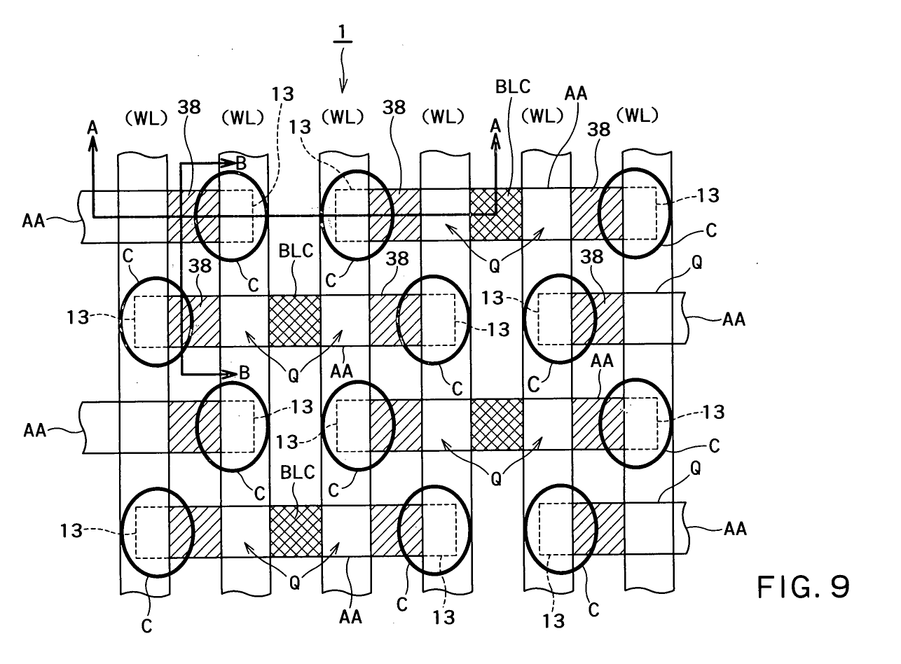

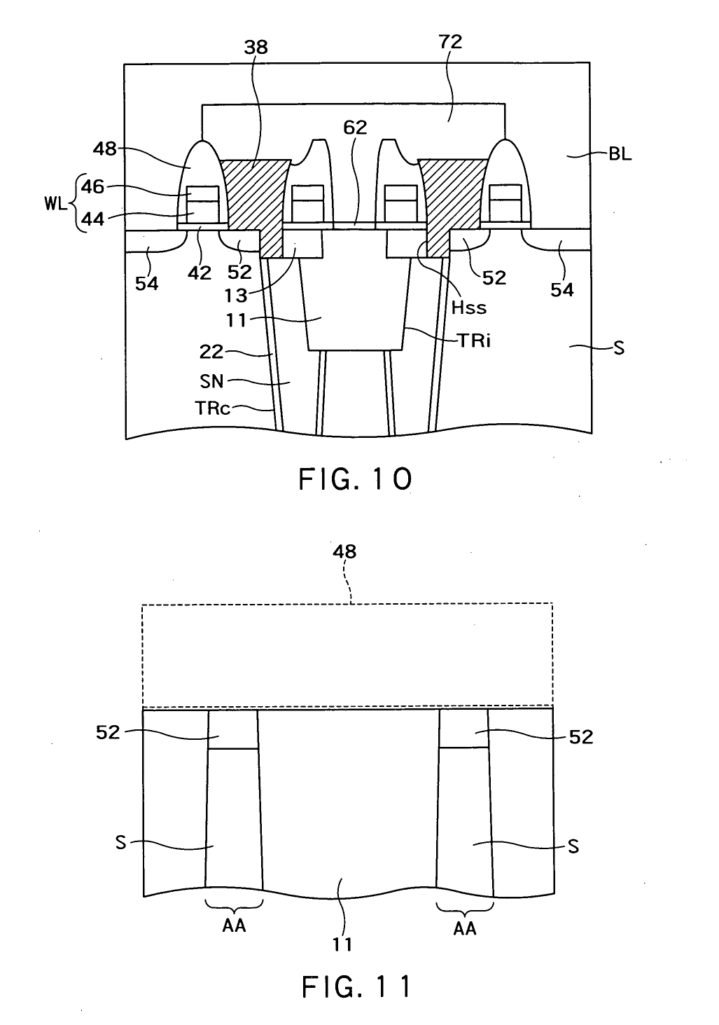

FIG. 9 shows a layout of a cell array area of a DRAM according to a first embodiment of the invention, and FIG. 10 and FIG. 11 are the sectional views along the line A-A, and the line B-B, respectively. One of characteristic features of a DRAM 1 of this embodiment lies in that it comprises a DT cap insulating film 13 formed of silicon nitride (SiN) film on the upper side of a trench capacitor C, thereby, when a TTO is etched back, a device isolation insulating film 11 on the sidewall of an AA can be prevented from being etched back. Now, starting from the schematic configuration of the DRAM 1, the first embodiment will be described below, step-by-step.

As shown in FIG. 9, the DRAM 1 of this embodiment comprises a trench capacitor C arranged and formed on a silicon substrate S, and a transistor Q formed on an AA which extends across neighboring two trench capacitors C and is partially overlapped with the trench capacitors C. As shown in FIG. 10 and FIG. 11, a device isolation trench TRi is formed in the surface layer of the silicon substrate S so as to define the AA, and the device isolation trench TRi is buried with oxide to form a device isolation insulating film 11 having a STI (Shallow Trench Insulator) structure.

The trench capacitor C is formed by burying a storage node SN into a trench TRc formed in the silicon substrate S. The trench TRc corresponds to a first trench for example, and on its upper portion, a collar insulating film 22 for isolating the trench capacitor C from the AA is formed of silicon oxide (SiO₂) film.

A plurality of transistors Q which respectively include a gate electrode formed on the silicon substrate S via a gate insulating film 42 so as to make a word line WL continuing in one direction, and source/drain diffusion layers 52, 54 formed in the surface layer of the silicon substrate S so as to sandwich the gate electrode, are formed in the AA. The gate electrode is configured with gate electrode polysilicon 44, in which tungsten silicide (WSi) 46 is formed on the top surface of the gate electrode polysilicon, and gate electrode cap silicon nitride (SiN) film 48 is formed on the side surface and on the top surface of the gate electrode. The gate electrode polysilicon 44 is formed of polysilicon doped with an impurity, for example; P. The source/drain diffusion layer 52 corresponds to the trench capacitor C, and the source/drain diffusion layer 54 is shared by neighboring two transistors Q and connected to a bit line BL formed in the upper layer portion of the gate electrode cap silicon nitride (SiN) film 48 via a bit line contact BLC.

As shown in FIG. 9, the AA and the trench capacitor C are formed so as to partially overlap each other. In the overlapped area, a DT cap insulating film 13 is formed such that it contacts the surface of the storage node SN of the trench capacitor C and faces to the source/drain diffusion layer 52 spaced apart by an SS contact hole Hss. The DT cap insulating film 13 is formed of insulating material that is different from that of the device isolation insulating film 11, in this embodiment, it is formed of silicon nitride (SiN) film. By filling the SS contact hole Hss, a buried contact layer (SS contact layer) 38 is formed of polysilicon doped with an impurity (for example; P) so as to extend across the both surfaces of the source/drain diffusion layer 52 and the storage node SN.

Since the DRAM 1 of this embodiment comprises an insulating film that may have selective ratios to the silicon substrate S and the silicon oxide (SiO₂) film, for example, a DT cap insulating film 13 formed of silicon nitride (SiN) film on the upper side of the trench capacitor C, the device isolation insulating film 11 on the sidewall of the AA is not removed during etching back the TTO, as shown in FIG. 11. Thereby, forming a buried contact layer 38 surely prevents the impurity (for example; P) in the polysilicon from diffusing into the AA side to change the concentration profile of the impurity of the source/drain diffusion layer 52.

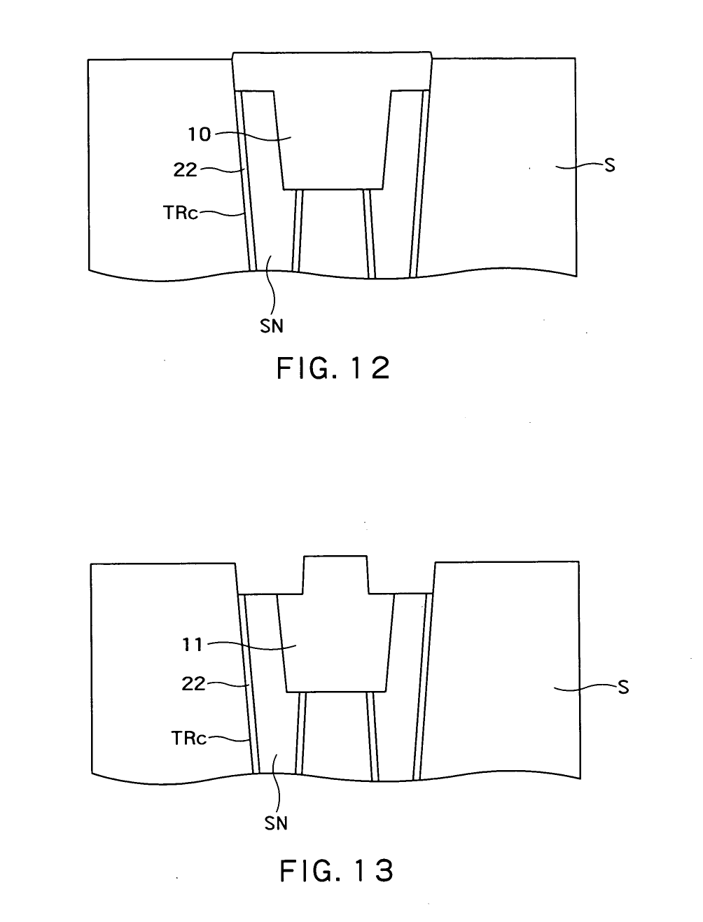

Now, referring to FIG. 12 to FIG. 18, a manufacturing method of the DRAM 1 shown in FIG. 9 to FIG. 11, will be described.

First, as shown in FIG. 12, by using a known technology, a trench capacitor C, collar oxide 22, and silicon oxide (SiO₂) film 10 that becomes a device isolation insulating film to define the AA are formed.

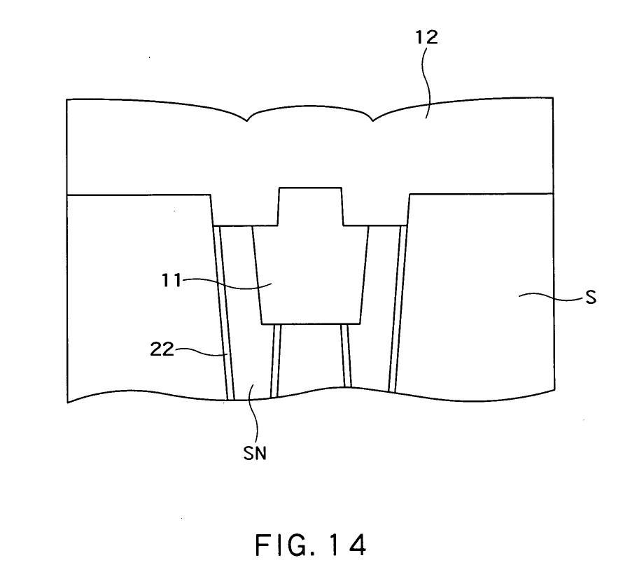

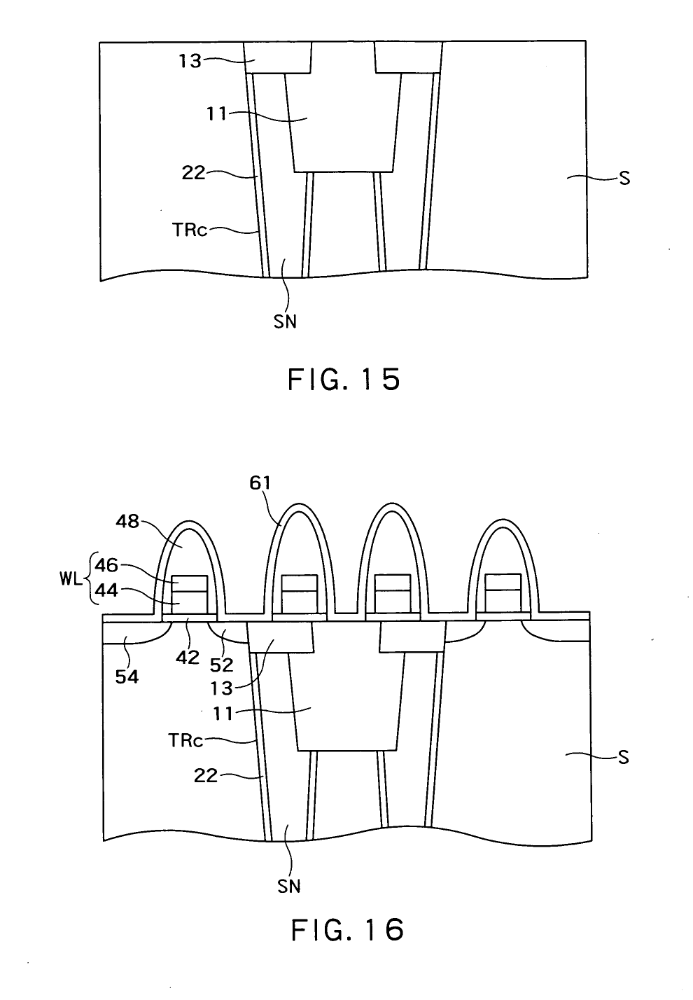

Next, as shown in FIG. 13, the portion of silicon oxide (SiO₂) film 10 that locates on the upper side of the trench is selectively removed until the top surface of a storage node SN is exposed by a photolithographic process and a dry etching process, using the mask as used when the trench capacitor C is formed. This results in forming a hole on the upper side of the trench TRc. The hole corresponds to a first hole, for example. Next, as shown in FIG. 14, an insulating film which may have selective ratios to the silicon substrate S and the silicon oxide (SiO₂) film, in this embodiment, silicon nitride (SiN) film 12, is deposited to a suitable film thickness. Then, as shown in FIG. 15, the silicon nitride (SiN) film 12 is planarized using a CMP (Chemical Mechanical Polishing) until the silicon substrate S is exposed, resulting in a situation that only the upper portion of the trench TRc is filled with silicon nitride (SiN) film 13. An etch back process of the silicon nitride (SiN) film 12 by an anisotropic etching may also be substituted for the polishing process of the silicon nitride (SiN) film 12 by the CMP. In this embodiment, it is important that only the upper portion of the trench TRc is filled with an insulating film different from the silicon oxide (SiO₂) film.

Then, as shown in FIG. 16, after a gate pattern is formed and source/drain diffusion layers 52, 54 of the AA are formed using a known technology, a barrier silicon nitride (SiN) film 61 is deposited. Further, after a gate interlayer film (not shown) is deposited, it is planarized.

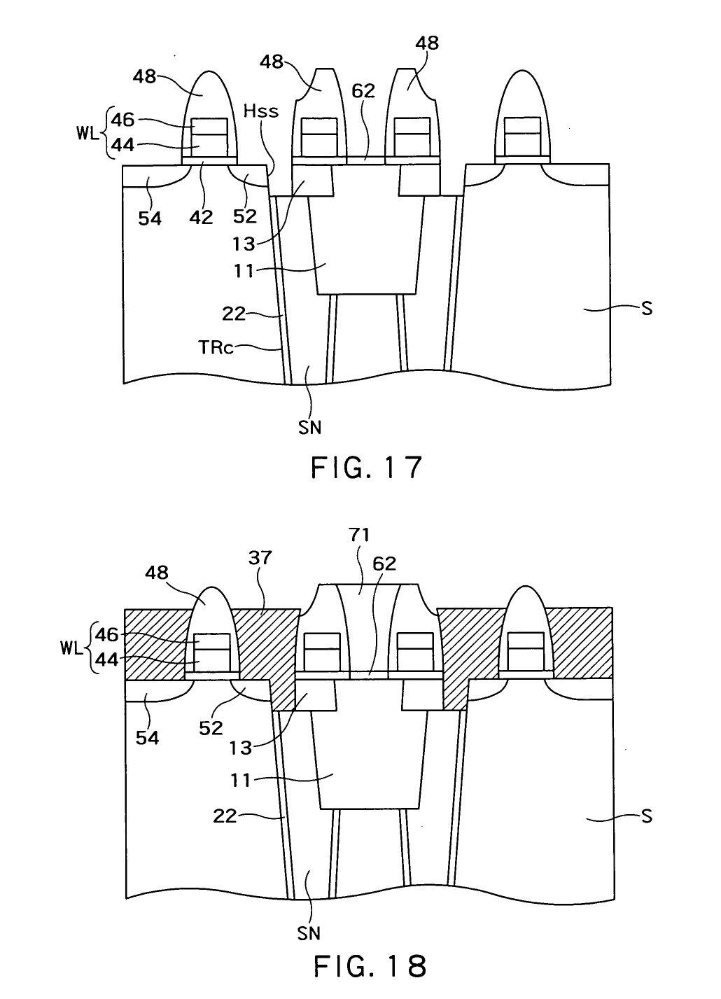

Next, the gate interlayer film of the area to which an SS contact hole Hss is provided, is selectively removed by a photolithographic process and a dry etching process, while using barrier silicon nitride (SiN) film 61 as an etch stop. Next, the barrier silicon nitride (SiN) film 61 is etched by an anisotropic etching, and finally, the insulating film on the upper side of the trench TRc is selectively removed to expose the top surface of the storage node SN. This embodiment uses silicon nitride (SiN) film 13 as an insulating film of the upper side of the trench TRc, thereby, as shown in FIG. 17, the silicon nitride (SiN) film 13 buried in the upper side of the trench TRc may also be removed by an etching back at the same time with the etching of the barrier silicon nitride (SiN) film 61. By this etching, the barrier silicon nitride (SiN) film 61 remains as a barrier silicon nitride (SiN) film 62 on the device isolation insulating film 11.

Then, after polysilicon doped with an impurity (for example; P) being deposited to a suitable thickness (for example; about 200 nm), as shown in FIG. 18, it is planarized to form a buried contact layer and etched back to a suitable depth. With these steps, an SS contact is formed. Then, after a BPSG film 72 (refers to FIG. 10) is formed using a conventional technology, it is planarized and a bit line BL is formed, thereby, resulting in completion of the DRAM 1.

### (2) Second Embodiment

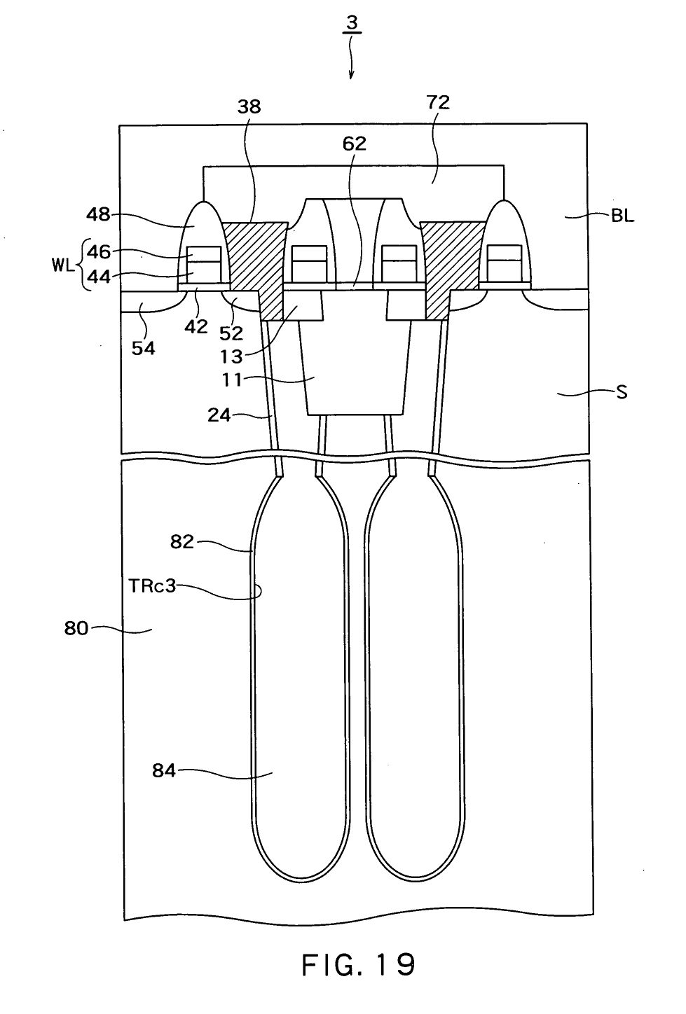

FIG. 19 is a sectional view of a DRAM according to a second embodiment of the present invention. In relation to the layout of a cell array area, FIG. 19 corresponds to the sectional view along the line A-A of FIG. 9.

Two of the characteristic features of a DRAM 3 shown in FIG. 19 are in that it includes a DT cap insulating film 13 to prevent the device isolation insulating film 11 of the sidewall of an AA from being etched back during etching back of a TTO and in that it includes a collar oxide 24 instead of the collar oxide 22 in FIG. 9. Differing in that the collar oxide 22 in FIG. 9 is formed by depositing an oxide on the capacitor trench TRc, the collar oxide 24 included by the DRAM 3 of this embodiment is formed by thermal oxidation of the silicon substrate S. This still allows a storage node SN to be surely formed by a conventional technology, even if the diameter of a capacitor trench becomes smaller as the finer design of the device further develops in future.

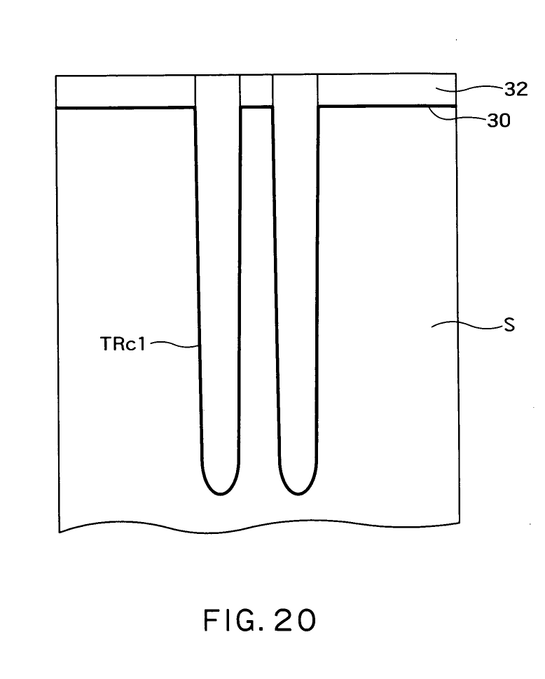

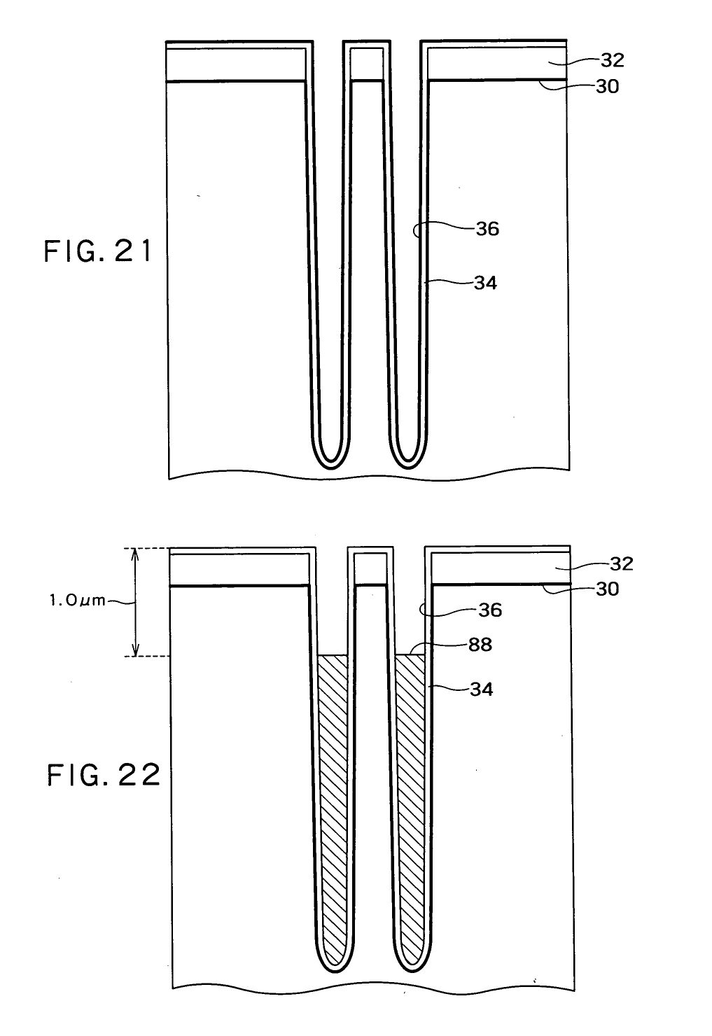

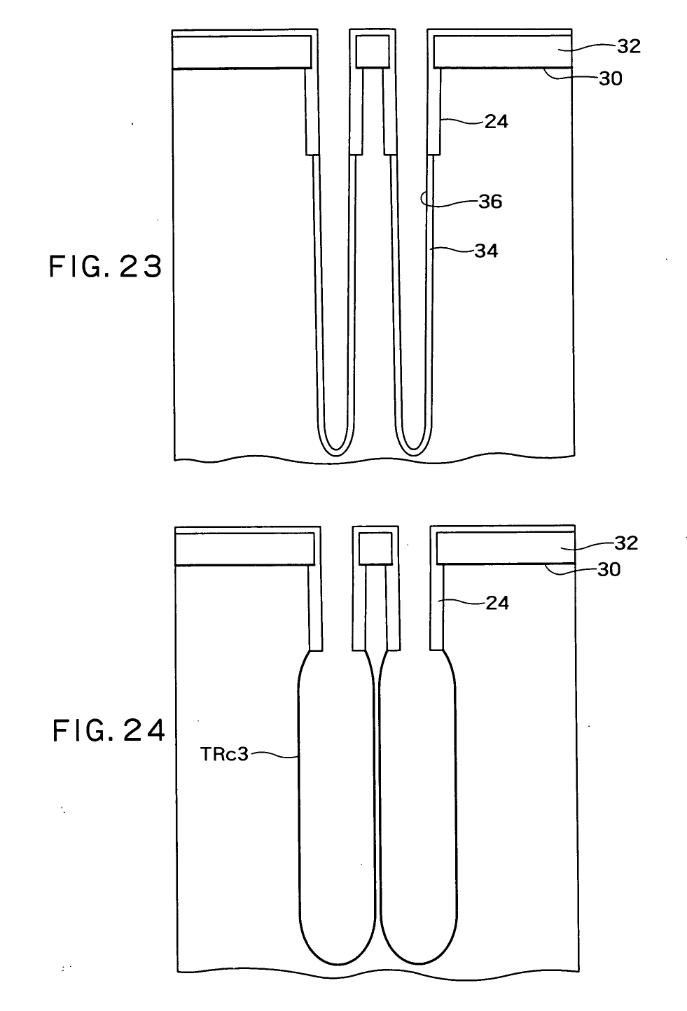

Now, referring to FIGS. 14-20, a manufacturing method of DRAM 3 of this embodiment will be described. First, as shown in FIG. 20, a pad silicon oxide (SiO₂) film (2 nm) and a pad silicon nitride (SiN) film (220 nm) are deposited on the silicon substrate S, and a capacitor trench TRc 1 is formed on the silicon substrate S by a photolithography process and a dry etching process. Next, as shown in FIG. 21, amorphous silicon 34 is deposited on the sidewall of the capacitor trench TRc 1 to a thickness of 30 nm, further, silicon nitride (SiN) film 36 is deposited to a thickness of 15 nm so as to cover the amorphous silicon 34. Then, as shown in FIG. 22, after a resist 88 being applied, the substrate is etched back to an appropriate depth, about 1.0 μm, for example. Further, after the silicon nitride (SiN) film 36 that is previously deposited on the sidewall of the capacitor trench TRc 1 and exposed is removed by a wet etching, the resist 88 is removed. Next, the amorphous silicon 34 on the upper sidewall of the capacitor trench TRc 1, which is exposed by removing the silicon nitride (SiN) film 36, is completely oxidized by thermally oxidizing the silicon substrate S, thereby, as shown in FIG. 23, a collar oxide 24 is formed. Next, the remaining silicon nitride (SiN) film 36 on the sidewall of the capacitor trench TRc 1 is completely removed by a wet etching. Next, as shown in FIG. 24, the sidewall of the capacitor trench TRc 1 that is not covered with the collar oxide 24 is etched by a CDE (Chemical Dry Etching) process or the like to enlarge the volume of the capacitor trench TRc 1, resulting in a capacitor trench TRc 3.

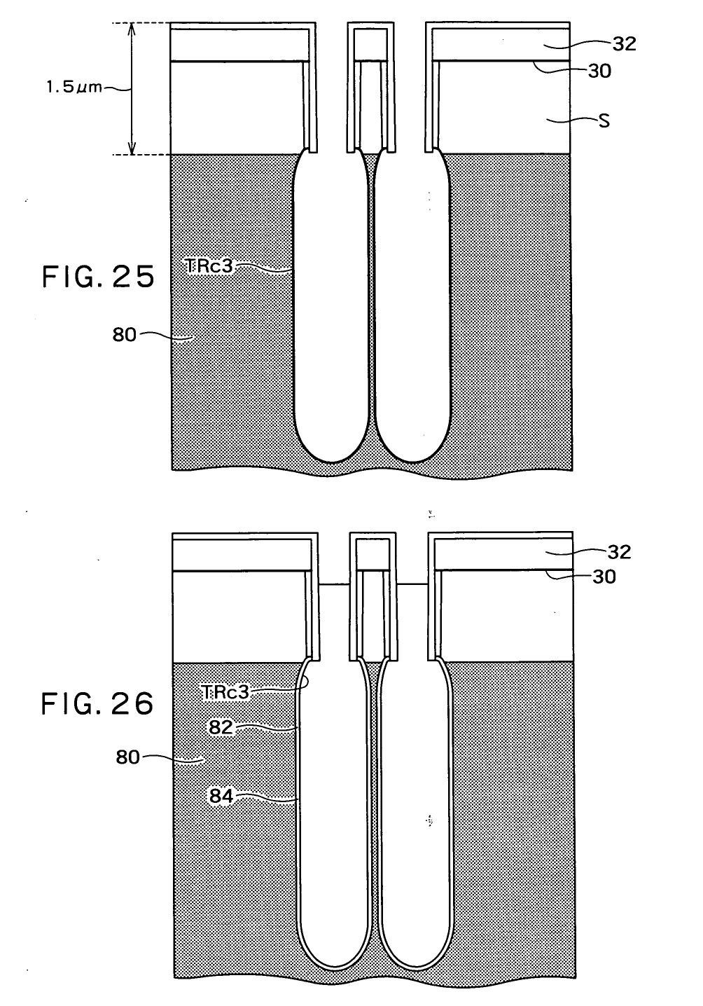

After then, as shown in FIG. 25, using a known technology, a buried plate 80 is formed by diffusing an n-type impurity into the area in the silicon substrate S that is deeper than 1.5 μm from the surface of the capacitor trench TRc 3. Then, as shown in FIG. 26, a capacitor dielectric film 82 is deposited on the sidewall of the capacitor trench TRc 3 to a thickness of 2-3 nm, which is filled with amorphous silicon doped with arsenide (As) and etched back to a required depth to make a contact between the corresponding source/drain diffusion layer 52 that becomes a storage node electrode and the storage node SN. Then, following the same steps as the first embodiment described above, an AA and a cell transistor Q are formed, and as shown in FIG. 19, an SS contact (a buried contact layer 38) is formed, further, using a known technology, DRAM 3 is completed.

As above, the embodiments according to the present invention have been described, however, the present invention is not limited to the above embodiments, and rather it may be performed in various changes within the scope thereof. For example, in the above second embodiment, in the step shown in FIG. 24, the volume of the capacitor trench TRc 1 is increased, however, this is an optional step, so depending upon the specification of product, this step may be omitted, and the volume of the capacitor trench TRc 1 may be still that of the conventional one.

What is claimed is:

1. A semiconductor memory device comprising:
a semiconductor substrate;
a plurality of trench capacitors each including a capacitor dielectric film formed on a sidewall of a first trench to be formed in the semiconductor substrate, a storage node formed so as to bury the first trench via the capacitor dielectric film, and a buried plate formed in the semiconductor substrate so as to surround the first trench;
a device isolation trench formed in the semiconductor substrate so as to define a device formation area across neighboring two trench capacitors;
a first insulating film for device isolation formed of a first insulating material to surround the device isolation trench;
a plurality of transistors formed on the device forming area respectively including a gate electrode formed on the semiconductor substrate via a gate insulating film so as to be a word line continuing in one direction and source/drain diffusion layers formed on the surface layer of the semiconductor substrate sandwiching the gate electrode such that one of them is shared and the other corresponds to the storage node;
a second insulating film formed on the upper side of the first trench so as to contact the top surface of the storage node and face the other source/drain diffusion layer spaced apart by a contact hole for a Surface Strap, the second insulating film being formed of a second insulating material different from the first material;
a buried contact layer formed so as to be self-aligned to the gate electrodes to bury the contact hole to connect the storage node and the other source/drain diffusion layer; and
a bit line to be connected to the one of the source/drain diffusion layers.

2. The semiconductor memory device according to claim 1,
wherein the second insulating material is insulating material which may have etching selective ratios to the semiconductor substrate and the first insulating material during forming the contact hole.

3. The semiconductor memory device according to claim 2, wherein the second insulating material is silicon nitride.

4. The semiconductor memory device according to claim 1, further comprising:
a collar insulating film formed on the upper side of the side wall of the capacitor node by thermal oxidation.

5. The semiconductor memory device according to claim 1,
wherein the first trench has a volume increased by etching the sidewall of the trench.

6. A manufacturing method of a semiconductor memory device comprises:
forming a plurality of trench capacitors by forming a plurality of first trenches on a semiconductor substrate, forming capacitor dielectric films on the sidewalls of the first trenches, forming storage nodes via the capacitor dielectric films so as to bury the first trenches, and forming buried plates in the areas of the semiconductor substrate that surrounds the first trenches;
forming a device isolation trench in the semiconductor substrate so as to define a device forming area extending across neighboring two trench capacitors;
forming a first insulating film for isolating a device by burying the device isolation trench;
forming a first hole from which the storage node is exposed by selectively removing a portion of the device isolation insulation film in the upper area of the first trench;
forming a second insulating film by filling the first hole with insulating material different from that of the first insulating film;
forming a plurality of transistors in the device forming area such that each gate electrode becomes a word line continuing to one direction, one of source/drain diffusion layers is shared by each transistor and the other source/drain diffusion layer corresponds to the storage node;
forming a barrier insulating film on the whole surface of the semiconductor substrate using an insulating material that may have etching selective ratios to the semiconductor substrate and the insulating material of the first insulating film:
forming a contact hole for a Surface Strap by selectively removing the second insulating film using the barrier insulating film as a mask until the top surface of the storage node and the other source/drain diffusion layer are exposed;
forming a buried contact layer so as to be self-aligned to the gate electrode to bury the contact hole; and
forming a bit line to be connected to the other source/drain diffusion layer.

7. The manufacturing method of a semiconductor device according to claim 6,
wherein the second insulating film is formed of the same insulating material as that of the barrier insulating film.

8. The manufacturing method of a semiconductor device according to claim 7, wherein the second insulating film is silicon nitride.

9. The manufacturing method of a semiconductor device according to claim 6, further comprising:
forming a collar insulating film on the upper portion of the sidewall of the capacitor node by thermal oxidation.

10. The manufacturing method of a semiconductor device according to claim 6, further comprising:
increasing the volume of the first trench by etching the sidewall of the first trench.
